(19) United States
(12) Patent Application Publication
(10) Pub. No.: US 2006/0211242 A1
(43) Pub. Date: Sep. 21, 2006

(54) METHOD OF FORMING A PLUG

(76) Inventors: Chia-Lin Hsu, Tai-Nan City (TW); Chih-Chan Yu, Kao-Hsiung Hsien (TW); Chien-Chung Huang, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/308,341

(22) Filed: Mar. 17, 2006

Related U.S. Application Data
(60) Provisional application No. 60/594,196, filed on Mar. 18, 2005.

(51) Int. Cl. H01L 21/44

(52) U.S. Cl. 438/675

(57) ABSTRACT

A method of forming a plug is provided. First, a substrate comprising at least a dielectric layer is provided, and a patterned hard mask is formed on the dielectric layer to define a position of at least a plug hole. Subsequently, the dielectric layer is etched for forming the plug hole. A barrier layer and a conductive layer are formed on the substrate, and the plug hole is filled by the conductive layer. Thereafter, first, second, and third chemical mechanical polishing processes are performed in turn. Finally, a fourth chemical mechanical polishing process is performed to remove portions of the conductive layer.

### CROSS REFERENCE TO RELATED APPLICATIONS

This application claims the benefit of U.S. Provisional Application No. 60/594,196 filed Mar. 18, 2005, and included herein by reference.

### BACKGROUND OF THE INVENTION

1. Field of the Invention

The present invention relates to a method of forming a plug. More particularly, the present invention relates to a method of integrating a step of removing a patterned hard mask into a chemical mechanical polishing process so as to form a plug.

2. Description of the Prior Art

Because of the superior step coverage and uniformity of the chemical vapor deposition (CVD) of tungsten, a hole can be filled up with tungsten without forming any void. Thus, the tungsten is widely applied to form the contact plugs or the via plugs in the semiconductor industry so as to electrically connect the former conductive layer with the latter conductive layer, such as electrically connecting a variety of the components with the leading wires.

The traditional process of forming the contact plugs or the via plugs utilizes a patterned photoresistor layer as an etching mask to etch a dielectric layer so as to form the needed plug holes. However, as the sizes of components get smaller, the thickness of the photoresistor layer should also decrease to avoid influencing the accuracy of the photolithographic process. As the photoresistor layer gets thinner, corners of the photoresistor layer may be cut or portions of the photoresistor layer may even be etched through before the plug hole etching process finishes. Subsequently, portions of the material layer, such as the dielectric layer, under the photoresistor layer are over exposed and etched. This etching of the exposed material layer is unnecessary and causes defects in the lower material layer. Thus, a process of forming a plug by utilizing a patterned hard mask is brought up to fit the manufacture of smaller size components. The process comprises etching the lower mask layer to form a patterned hard mask by utilizing the upper patterned photoresistor layer as a etching mask, removing the patterned photoresistor layer, and etching the dielectric layer to form at least a contact plug hole or a via plug hole by utilizing the patterned hard mask as a etching mask.

Please refer to FIG. 1 through FIG. 6. FIG. 1 through FIG. 6 are schematic diagrams illustrating a method of forming plugs 28 by utilizing a patterned hard mask 18 according to the prior art. As shown in FIG. 1, first, a substrate 10 is provided, and the substrate 10 comprises at least a dielectric layer 12. Next, a mask layer 14 and a photoresistor layer 16 are formed in turn on the dielectric layer 12. As shown in FIG. 2, a plurality of openings, such as two openings, are formed in the photoresistor layer 16 by an exposure-and-development process to expose portions of the mask layer 14. As shown in FIG. 3, the mask layer 14 is etched to be a patterned hard mask 18 by utilizing the photoresistor layer 16 as an etching mask. The photoresistor layer 16 is removed after forming the patterned hard mask 18. As shown in FIG. 4, the dielectric layer 12 is etched by utilizing the patterned hard mask 18 as an etching mask so as to form a plurality of plug holes 22 in the dielectric layer 12. The patterned hard mask 18 is removed after the plug holes 22 are formed so as to decrease the aspect ratio. As shown in FIG. 5, after the patterned hard mask 18 is removed, a barrier layer 24 and a conductive layer 26 are formed in turn on the substrate 10, and the plug holes 22 are filled by the conductive layer 26. As shown in FIG. 6, subsequently a chemical mechanical polishing (CMP) process is performed. The CMP process utilizes a kind of slurry to remove portions of the conductive layer 26 and portions of the barrier layer 24 on two platens respectively or only on one platen. Finally, an oxide buffing process is performed to remove portions of the dielectric layer 12. Thus, a plurality of extrude plugs 28 is formed in the dielectric layer 12.

Although the prior art process of forming the plug holes 22 by utilizing the patterned hard mask 18 as an etching mask can overcome the obstacle of the traditional process which utilizes a patterned photoresistor layer as an etching mask, the prior art process causes a higher electric resistance of the plugs 28. Because the patterned hard mask 18 is removed before forming the barrier layer 24 and the conductive layer 26, the step of removing the patterned hard mask 18 may cause some defects, such as damage to the plug holes 22, over etching the plug holes 22, or particles of the etching process falling into the plug holes 22. The above mentioned defects result in a higher electric resistance of the plugs 28. Usually, there are millions of the plugs 28 in the integrated circuit for electrical connection, so the higher electric resistances of the plugs 28 are undesirable. As a result, the prior art method of forming plugs 28 by utilizing a patterned hard mask 18 should be developed to increase the efficiency of the whole integrated circuit.

### SUMMARY OF THE INVENTION

It is therefore a primary object of the claimed invention to provide a method of forming a plug to overcome the aforementioned problems.

According to the present invention, a method for forming a plug includes providing a substrate, the substrate comprising at least a dielectric layer, forming a patterned hard mask on the dielectric layer, etching the dielectric layer to form at least a plug hole by utilizing the patterned hard mask as a mask, forming a barrier layer on the dielectric layer, the barrier layer covering a surface of the patterned hard mask, a side and a bottom of the plug hole, forming a conductive layer on the barrier layer, the conductive layer filling up the plug hole, performing a first chemical mechanical polishing process which uses the barrier layer as a stop layer to remove portions of the conductive layer, performing a second chemical mechanical polishing process which uses the patterned hard mask as a stop layer to remove portions of the barrier layer, performing a third chemical mechanical polishing process to remove the patterned hard mask, and performing a fourth chemical mechanical polishing process to remove portions of the dielectric layer.

Because the present invention integrates a step of removing a patterned hard mask into a chemical mechanical polishing process, the present invention avoids the defects, such as damage to the plug hole, over etching the plug hole, or fragments of the patterned hard mask falling into the plug hole. Thus, the electric resistance of the plug decreases. Additionally, the process of forming a plug is simplified. As a result, the efficiency of the integrated circuit is developed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 6 are schematic diagrams illustrating a method of forming plugs by utilizing a patterned hard mask according to the prior art.

FIG. 7 through FIG. 14 are schematic diagrams illustrating a method of forming a conductive plug according to the first preferred embodiment of the present invention.

FIG. 15 through FIG. 18 are schematic diagrams illustrating a method of forming a conductive plug according to the fifth preferred embodiment of the present invention.

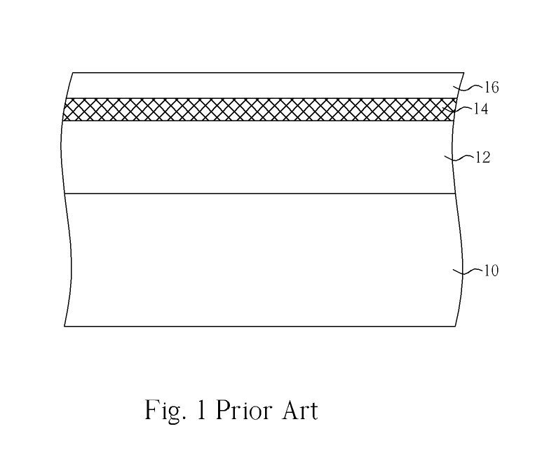

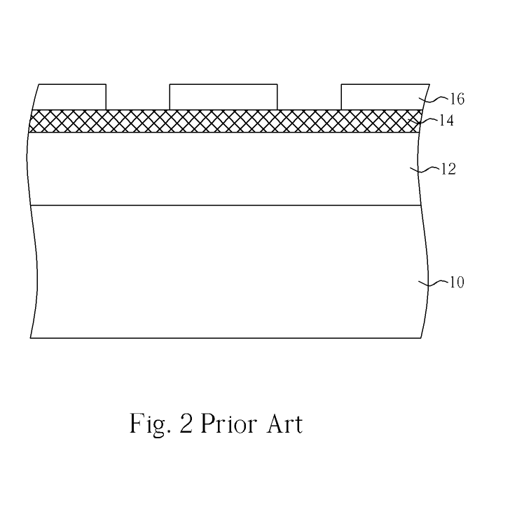

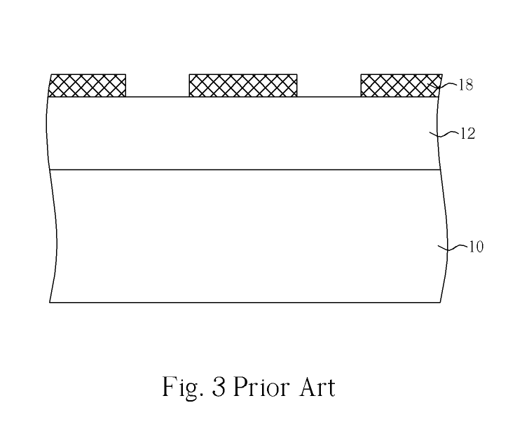

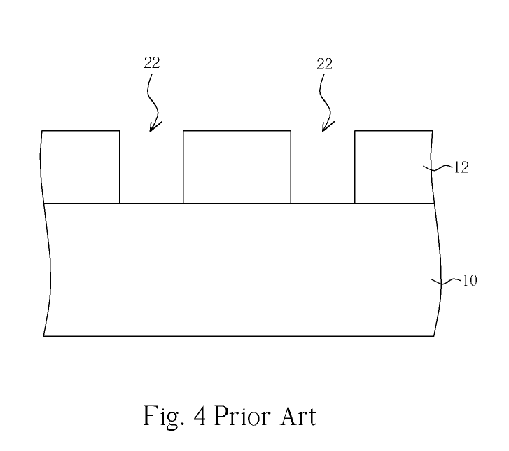

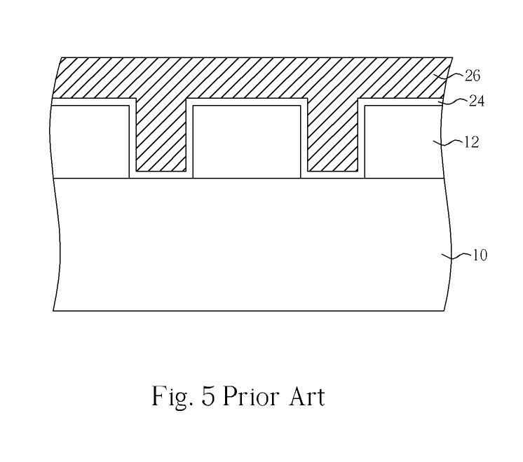

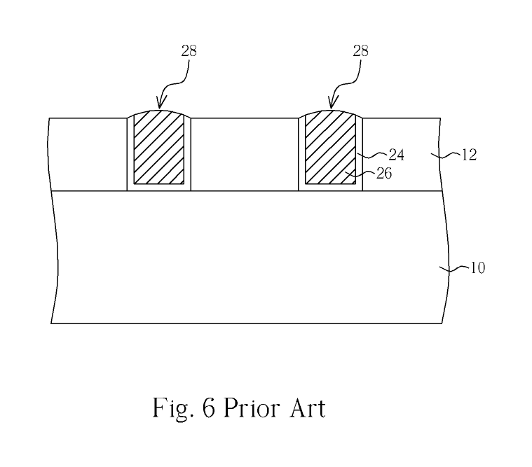

### DETAILED DESCRIPTION

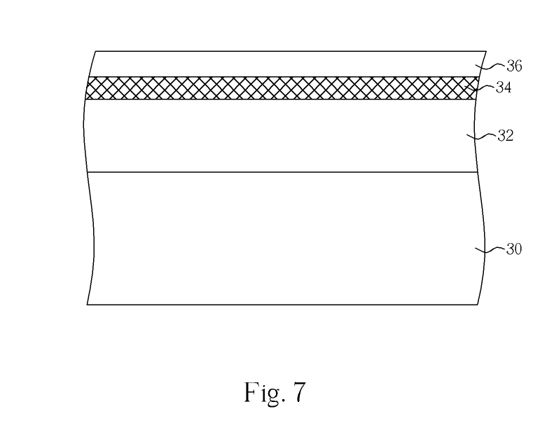

Please refer to FIG. 7 through FIG. 14. FIG. 7 through FIG. 14 are schematic diagrams illustrating a method of forming a conductive plug according to the first preferred embodiment of the present invention. As shown in FIG. 7, first, a substrate 30 is provided, and the substrate 30 comprises at least a dielectric layer 32. The substrate 30 may be a wafer or a silicon-on-insulator (SOI) substrate used in semiconductor industry, and the dielectric layer 32 comprises the dielectric materials, such as silicon oxide which may be formed by a variety of the chemical vapor deposition process or by a way of spin-on process. Next, a mask layer 34 and a photoresistor layer 36 are formed in turn on the dielectric layer 32. The mask layer 34 comprises materials with better etch resistance, such as silicon oxide nitride compounds, silicon nitride compounds or siliconcarbon.

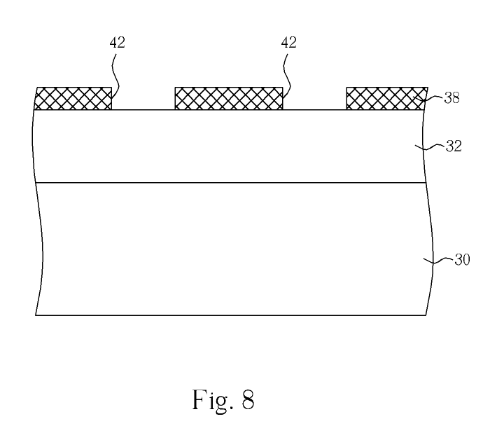

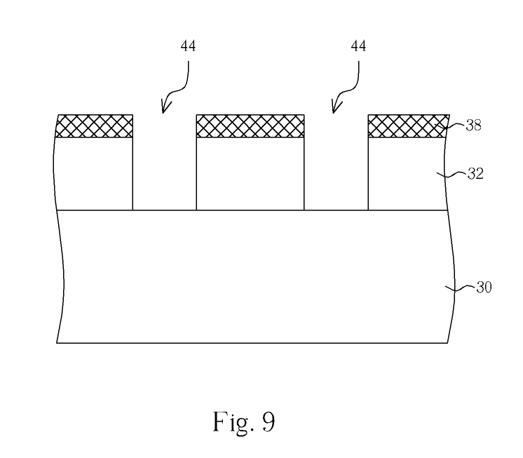

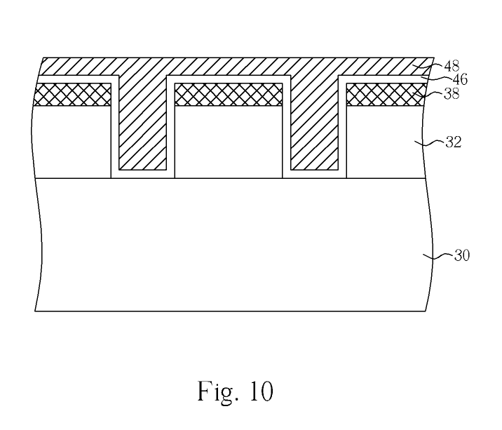

As shown in FIG. 8, an exposure-and-development process is performed on the photoresistor layer 36 so as to turn the photoresistor layer 36 into a patterned photoresistor layer by a step of pattern transferring. Next, the mask layer 34 is etched by utilizing the patterned photoresistor layer as an etching mask to form at least an opening 42. For example, two openings 42 are formed in this preferred embodiment. Each opening 42 is formed to define a position of a plug hole 44. The photoresistor layer 36 is removed after forming the patterned hard mask 38. As shown in FIG. 9, the dielectric layer 32 is etched by utilizing the patterned hard mask 38 as an etching mask so as to form the corresponding plug holes 44 in the dielectric layer 32. As shown in FIG. 10, a barrier layer 46 and a conductive layer 48 are formed in turn on the substrate 30. The barrier layer 46 covers the surface of patterned hard mask 38, the dielectric layer 32 in the plug holes 44, and the substrate 30 in the plug holes 44. The plug holes 44 are filled by the conductive layer 48. Preferably, the material of the barrier layer 46 comprises metals which provide good adhesion and protection, such as titanium, tantalum, titanium nitride and tantalum nitride. The material of conductive layer 48 comprises metals or alloys with good superior step coverage and uniformity, such as tungsten in this preferred embodiment. The material of the conductive layer 48 is not limited only to tungsten, but can also be aluminum, copper, or an alloy thereof.

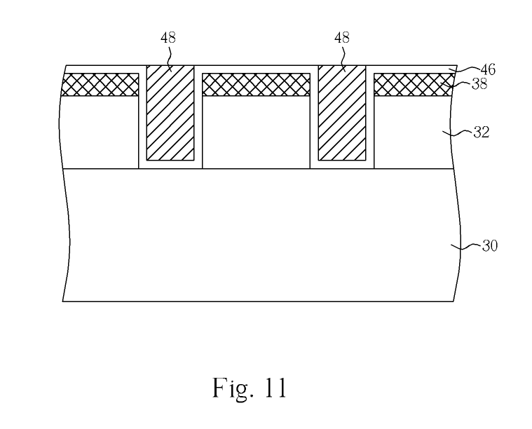

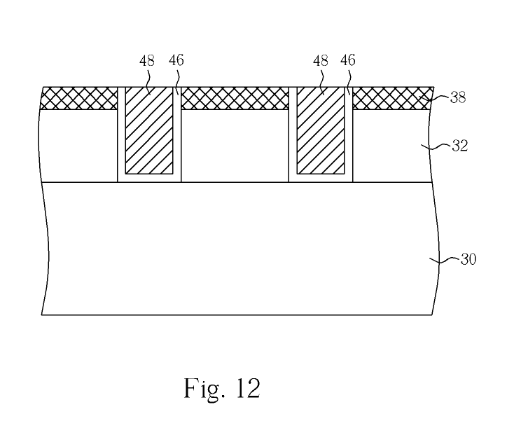

As shown in FIG. 11, a first chemical mechanical polishing process is performed, which uses the barrier layer 46 as a stop layer to remove portions of the conductive layer 48. Subsequently, as shown in FIG. 12, a second chemical mechanical polishing process is performed, which uses the patterned hard mask 38 as a stop layer to remove portions of the barrier layer 46. In the first preferred embodiment, the first chemical mechanical polishing process and the second chemical mechanical polishing process both use a first slurry to polish on a first platen. The first slurry has an etching selectivity ratio of the conductive layer 48 to the patterned hard mask 38, and the etching selectivity ratio is about greater than 10. Additionally, the first slurry has an etching selectivity ratio of the barrier layer 46 to the patterned hard mask 38, and the etching selectivity ratio is about 2 or greater than 2. Because the etching selectivity ratio is about 2 or greater than 2, polishing process from the barrier layer 46 to the patterned hard mask 38 can be detected. Thus, the step of using the patterned hard mask 38 as a stop layer can be achieved. Said first slurry is a metal slurry which can polish metal materials. For example, the metal slurry can be a potassium ferricyanide solution, a ferric nitrate solution, or a hydrogen peroxide solution, which comprises abrasives such as alumina suspensions.

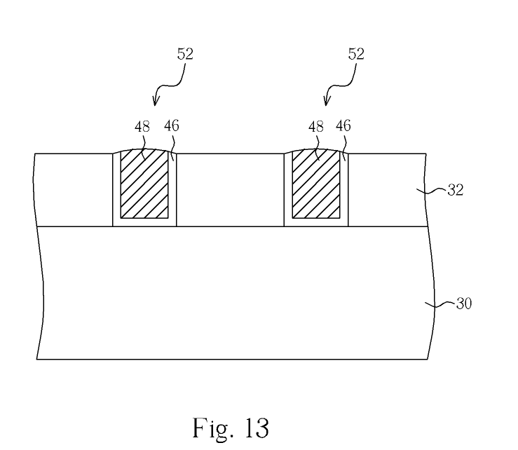

As shown in FIG. 13, a third chemical mechanical polishing process is performed, which uses a second slurry to polish on a second platen to remove the patterned hard mask 38 and to comparatively extrude portions of the conductive layer 48 and portions of the barrier layer 46. Preferably, the second slurry has an etching selectivity ratio of the patterned hard mask 38 to the conductive layer 48, and the etching selectivity ratio is about 1 or greater than 1. Because the etching selectivity ratio of the patterned hard mask 38 to the conductive layer 48 is about 1 or greater than 1, the removal rate of the conductive layer 48 can be slower than the removal rate of the patterned hard mask 38. As a result, portions of the conductive layer 48 and portions of the barrier layer 46 can extrude from the surface of the dielectric layer 32 to form the tungsten plugs 52. Said second slurry is an oxide slurry which can polish dielectric materials. For example, the oxide slurry can include a colloidal solution and an alkaline additive, and the alkaline additive may be an alkaline substance, such as potassium hydroxide or ammonium hydroxide, to adjust the pH value of the oxide slurry.

As the removal rate of the patterned hard mask 38 is obviously faster than the removal rate of the dielectric layer 32, portions of the conductive layer 48 and portions of the barrier layer 46 can extrude from a surface of the dielectric layer 32 after the third chemical mechanical polishing process, and the corresponding tungsten plugs 52 are formed. Thus, the extruded plugs can be formed without hugely polishing the dielectric layer 32. In other words, because the dielectric layer 32 of the present invention is less consumed, the initial thickness of the formed dielectric layer 32 can be thinner.

The first, the second and the third chemical mechanical polishing processes can individually polish on three different platens, and it depends on the process design or the materials which are polished. According to the second preferred embodiment of the present invention, a substrate 30 and at least a dielectric layer 32 are provided. Two plug holes 44 are formed in the dielectric layer 32, and the plug holes 44 are filled by a barrier layer 46 and a conductive layer 48. The above-mentioned steps are similar to the steps of the first embodiment, so they are not described in detail again. Subsequently, a first chemical mechanical polishing process is performed on a first platen utilizing the first slurry to remove portions of the conductive layer 48. Next, a second chemical mechanical polishing process is performed on a second platen utilizing the first slurry to remove portions of the barrier layer 46. Finally, a third chemical mechanical polishing process is performed on a third platen utilizing a second slurry to remove portions of the patterned hard mask 38 and form the extruded tungsten plugs 52.

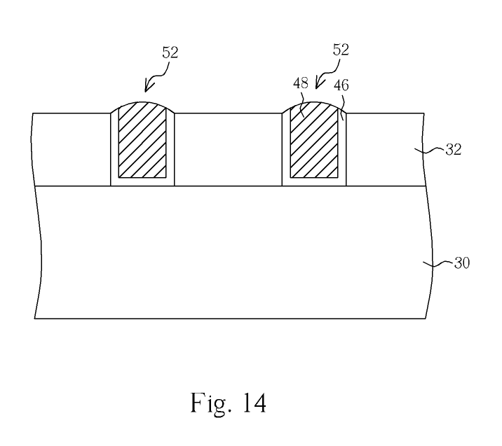

In addition, according to the third preferred embodiment of the present invention, an oxide buffing process can be further performed to more extrude the metal plugs after performing the third chemical mechanical polishing process by the first preferred embodiment. As shown in FIG. 14, a fourth chemical mechanical polishing process is performed, which utilizes a third slurry to remove portions of the dielectric layer 32 on a third platen as the oxide buffing process. Portions of the conductive layer 48 and portions of the barrier layer 46 are therefore more extruded from a surface of the dielectric layer 32.

Otherwise, according to the fourth preferred embodiment of the present invention, a fourth chemical mechanical polishing process can be further performed to more extrude the metal plugs after performing the third chemical mechanical polishing process by the first preferred embodiment. The fourth chemical mechanical polishing process utilizes the second slurry to remove portions of the dielectric layer 32 on a third platen. Thus, portions of the conductive layer 48 and portions of the barrier layer 46 are more extruded from the surface of the dielectric layer 32.

It deserves to be mentioned that the first chemical mechanical polishing process and the second chemical mechanical polishing process both use the first slurry to polish in the previous embodiments.

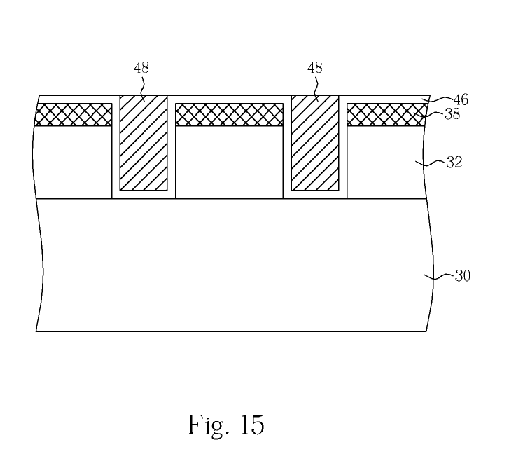

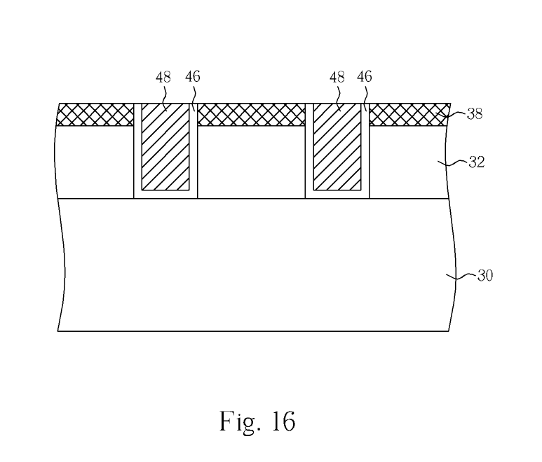

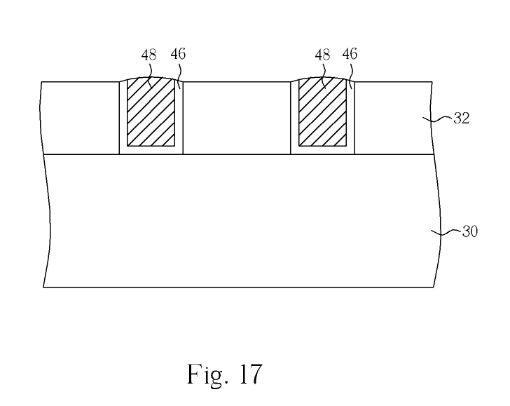

Please refer to FIG. 15 through FIG. 18. FIG. 15 through FIG. 18 are schematic diagrams illustrating a method of forming a conductive plug according to a fifth preferred embodiment of the present invention. The steps of this embodiment for forming a tungsten plug 52 are similar to the steps of the first prefered embodiment from FIG. 7 to FIG. 10, but the steps of this embodiment are different from the steps of the previous embodiment after filling up the plug holes 44. In order to compare to the previous embodiment, same labels will be carried forward through FIG. 15 to FIG. 18. As shown in FIG. 7 to FIG. 10, a substrate 30 and at least a dielectric layer 32 are provided. Two plug holes 44 are formed in the dielectric layer 32, and the plug holes 44 are filled by a barrier layer 46 and a conductive layer 48. These steps are mentioned above, so they are not described in detail again. Subsequently, as shown in FIG. 15, a first chemical mechanical polishing process is performed, which uses the barrier layer 46 as a stop layer to remove portions of the conductive layer 48. As shown in FIG. 16, a second chemical mechanical polishing process is performed, which uses the patterned hard mask 38 as a stop layer to remove portions of the barrier layer 46. Next, as shown in FIG. 17, a third chemical mechanical polishing process is performed to remove the patterned hard mask 38.

In the fifth preferred embodiment, the first and the second chemical mechanical polishing process use a fifth slurry to polish on the first platen, and the third chemical mechanical polishing process uses the fifth slurry to polish on the second platen. The fifth slurry has an etching selectivity ratio of the patterned hard mask 38 to the conductive layer 48, and the etching selectivity ratio is about 1 or greater than 1. Because the etching selectivity ratio of the patterned hard mask 38 to the conductive layer 48, portions of the conductive layer 48 and portions of the barrier layer 46 can slightly extrude from the surface of the dielectric layer 32.

According to the sixth preferred embodiment of the present invention, a substrate 30 and at least a dielectric layer 32 are provided. Two plug holes 44 are formed in the dielectric layer 32, and the plug holes 44 are filled by a barrier layer 46 and a conductive layer 48. These steps are mentioned above in the fifth embodiment, so they are not described in detail again. Subsequently, a first chemical mechanical polishing process is performed on a first platen utilizing the fourth slurry to remove portions of the conductive layer 48. Next, a second chemical mechanical polishing process is performed on a second platen utilizing the fourth slurry to remove portions of the barrier layer 46. Finally, a third chemical mechanical polishing process is performed on the second platen or on a third platen utilizing the fourth slurry to remove portions of the patterned hard mask 38 and form the extruded tungsten plugs 52.

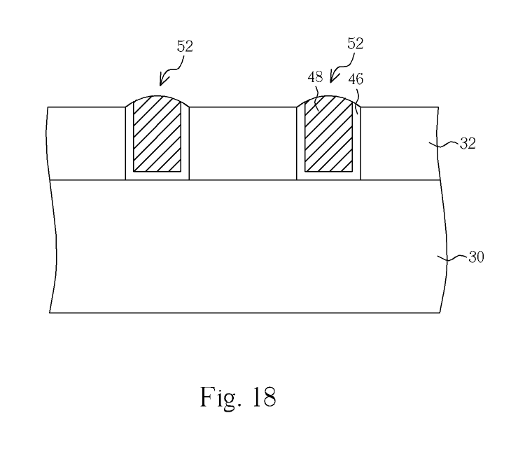

According to the seventh preferred embodiment of the present invention, after performing the third chemical mechanical polishing process by the fifth embodiment, a fourth chemical mechanical polishing process is performed on a third platen utilizing the fifth slurry, If the metal plugs should be more extrude. As shown in FIG. 18, a fourth chemical mechanical polishing process is performed to remove portions of the dielectric layer 32. Portions of the conductive layer 48 and portions of the barrier layer 46 more extrude from a surface of the dielectric layer 32 after the fourth chemical mechanical polishing process, thereby forming corresponding tungsten plugs 52.

Otherwise, according to the eighth preferred embodiment of the present invention, a substrate 30 and at least a dielectric layer 32 are provided. Two plug holes 44 are formed in the dielectric layer 32, and the plug holes 44 are filled by a barrier layer 46 and a conductive layer 48. These steps are similar to the steps of the fifth embodiment. Subsequently, a first chemical mechanical polishing process is performed on a first platen utilizing the fourth slurry to remove portions of the conductive layer 48. Next, a second chemical mechanical polishing process and a third chemical mechanical polishing process are performed on a second platen utilizing the fourth slurry to remove portions of the barrier layer 46 and portions of the patterned hard mask 38. Finally, a fourth chemical mechanical polishing process is performed on a third platen utilizing the fifth slurry to remove and form the extruded tungsten plugs 52.

It deserves to be mentioned that the first, the second and the third chemical mechanical polishing process all use the fourth slurry for polishing in the fifth to the eighth embodiments.

The patterned hard mask 38 is not removed right after the step of forming the plug holes 44 in the present invention, but the present invention integrates the step of removing a patterned hard mask 38 into a chemical mechanical polishing process instead. Because the plug holes 44 are already filled up by the barrier layer 46 and the conductive layer 48 while the patterned hard mask 38 is removed, the present invention avoids the defects, such as damage to the side and the bottom of the plug hole 44 or over etching the plug hole 44. For the same reason, the fragments of the patterned hard mask 38 do not fall into the plug holes 44 while the patterned hard mask 38 is removed. As a result, the present invention can reduce the electric resistance of the tungsten plugs 52, and then the efficiency of the integrated circuit is increased. In addition, because the present invention can extrude portions of the conductive layer and portions of the barrier layer from the surface of the dielectric layer utilizing the third chemical mechanical polishing process, the initial thickness of the formed dielectric layer can be thinner.

Furthermore, the present invention not only reduces the electric resistance of the tungsten plug 52, but also simplifies the process of forming the tungsten plug 52. If the patterned hard mask 38 is removed right after the step of etching the dielectric layer 32 to form the plug hole 44, the etching process and the polishing process, may be further performed on the substrate 30 in order to remove the patterned hard mask 38. If the step of removing a patterned hard mask 38 is integrated into the chemical mechanical polishing process, portions of the conductive layer 48, portions of the barrier layer 46, the patterned hard mask 38, and portions of the dielectric layer 32 are removed at the same time. Thus, the process of forming the conductive plug is simplified.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a plug, comprising:
providing a substrate, the substrate comprising at least a dielectric layer;
forming a patterned hard mask on the dielectric layer;
etching the dielectric layer to form at least a plug hole by utilizing the patterned hard mask as a mask;
forming a barrier layer on the dielectric layer, the barrier layer covering a surface of the patterned hard mask, a side and a bottom of the plug hole;
forming a conductive layer on the barrier layer, the conductive layer filling up the plug hole;
performing a first chemical mechanical polishing process which uses the barrier layer as a stop layer to remove portions of the conductive layer;
performing a second chemical mechanical polishing process which uses the patterned hard mask as a stop layer to remove portions of the barrier layer;
performing a third chemical mechanical polishing process which uses the dielectric layer as a stop layer to remove the patterned hard mask; and
performing a fourth chemical mechanical polishing process to remove portions of the dielectric layer.

2. The method of claim 1, wherein the substrate comprises a wafer or a silicon-on-insulator.

3. The method of claim 1, wherein the plug hole comprises a contact plug hole or a via plug hole.

4. The method of claim 1, wherein the step of forming a patterned hard mask further comprises:
providing a mask layer and a photoresistor layer in turn;
performing an exposure-and-development process on the photoresistor layer so as to turn the photoresistor layer into a patterned photoresistor layer;
etching the mask layer to form at least an opening by utilizing the patterned photoresistor layer as a mask so as to define a position of the plug hole; and
removing the patterned photoresistor layer.

5. The method of claim 4, wherein the mask layer comprises silicon oxide nitride compounds, silicon nitride compounds or siliconcarbon.

6. The method of claim 1, wherein the first chemical mechanical polishing process and the second chemical mechanical polishing process both use a first slurry for polishing.

7. The method of claim 6, wherein the first chemical mechanical polishing process is performed on a first platen.

8. The method of claim 7, wherein the second chemical mechanical polishing process is performed on the first platen.

9. The method of claim 6, wherein the first slurry has an etching selectivity ratio of the barrier layer to the patterned hard mask, and the etching selectivity ratio is greater than 2.

10. The method of claim 6, wherein the first slurry has an etching selectivity ratio of the conductive layer to the patterned hard mask, and the etching selectivity ratio is greater than 10.

11. The method of claim 1, wherein the third chemical mechanical polishing process and the fourth chemical mechanical polishing process both use a second slurry for polishing.

12. The method of claim 1, wherein the third chemical mechanical polishing process uses a second slurry for polishing and the fourth chemical mechanical polishing process uses a third slurry for polishing.

13. The method of claim 8, wherein the third chemical mechanical polishing process is performed on a second platen.

14. The method of claim 13, wherein the fourth chemical mechanical polishing process is performed on a third platen.

15. The method of claim 11 or claim 12, wherein the second slurry has an etching selectivity ratio of the patterned hard mask to the conductive layer, and the etching selectivity ratio is greater than 1.

16. The method of claim 1, wherein the first chemical mechanical polishing process, the second chemical mechanical polishing process and the third chemical mechanical polishing process all use a fourth slurry for polishing.

17. The method of claim 1, wherein the fourth chemical mechanical polishing process uses a fifth slurry for polishing.

18. The method of claim 16, wherein the first chemical mechanical polishing process is performed on a first platen.

19. The method of claim 18, wherein the second chemical mechanical polishing process is performed on the first platen.

20. The method of claim 18, wherein the second chemical mechanical polishing process is performed on a second platen.

21. The method of claim 19, wherein the third chemical mechanical polishing process is performed on a second platen.

22. The method of claim 20, wherein the third chemical mechanical polishing process is performed on the second platen.

23. The method of claim 21 or claim 22, wherein the fourth chemical mechanical polishing process is performed on a third platen.

24. The method of claim 16, wherein the fourth slurry has an etching selectivity ratio of the patterned hard mask to the conductive layer, and the etching selectivity ratio is greater than 1.

25. The method of claim 1, wherein the conductive layer comprises tungsten, aluminum, copper, or an alloy thereof.

26. The method of claim 1, wherein the barrier layer is selected from a group consisting of titanium, tantalum, titanium nitride and tantalum nitride.

27. The method of claim 1, wherein the dielectric layer comprises silicon oxide.

28. The method of claim 1, wherein portions of the conductive layer and portions of the barrier layer extrude from a surface of the dielectric layer after the fourth chemical mechanical polishing process, thereby forming an extruded plug.

29. A method of forming a plug, comprising:
providing a substrate, the substrate comprising at least a dielectric layer;
forming a patterned hard mask on the dielectric layer;
etching the dielectric layer to form at least a plug hole by utilizing the patterned hard mask as a mask;
forming a barrier layer on the dielectric layer, the barrier layer covering a surface of the patterned hard mask, a side and a bottom of the plug hole;
forming a conductive layer on the barrier layer, the conductive layer filling up the plug hole;
performing a first chemical mechanical polishing process which uses the barrier layer as a stop layer to remove portions of the conductive layer;
performing a second chemical mechanical polishing process which uses the patterned hard mask as a stop layer to remove portions of the barrier layer; and
performing a third chemical mechanical polishing process which uses the dielectric layer as a stop layer to remove the patterned hard mask.

30. The method of claim 29, wherein portions of the conductive layer and portions of the barrier layer extrude from a surface of the dielectric layer after the third chemical mechanical polishing process, thereby forming an extruded plug.

31. The method of claim 29, wherein the first chemical mechanical polishing process and the second chemical mechanical polishing process both use a first slurry for polishing.

32. The method of claim 31, wherein the first chemical mechanical polishing process is performed on a first platen.

33. The method of claim 32, wherein the second chemical mechanical polishing process is performed on the first platen.

34. The method of claim 32, wherein the second chemical mechanical polishing process is performed on a second platen.

35. The method of claim 31, wherein the first slurry has an etching selectivity ratio of the barrier layer to the patterned hard mask, and the etching selectivity ratio is greater than 2.

36. The method of claim 31, wherein the first slurry has an etching selectivity ratio of the conductive layer to the patterned hard mask, and the etching selectivity ratio is greater than 10.

37. The method of claim 29, wherein the third chemical mechanical polishing process and the fourth chemical mechanical polishing process both use a second slurry for polishing.

38. The method of claim 33, wherein the third chemical mechanical polishing process is performed on a second platen.

39. The method of claim 34, wherein the third chemical mechanical polishing process is performed on a third platen.

40. The method of claim 37, wherein the second slurry has an etching selectivity ratio of the patterned hard mask to the conductive layer, and the etching selectivity ratio is greater than 1.

41. The method of claim 29, wherein the first chemical mechanical polishing process, the second chemical mechanical polishing process and the third chemical mechanical polishing process all use a fourth slurry for polishing.

42. The method of claim 41, wherein the first chemical mechanical polishing process is performed on a first platen.

43. The method of claim 42, wherein the second chemical mechanical polishing process is performed on the first platen.

44. The method of claim 42, wherein the second chemical mechanical polishing process is performed on a second platen.

45. The method of claim 43, wherein the third chemical mechanical polishing process is performed on a second platen.

46. The method of claim 44, wherein the third chemical mechanical polishing process is performed on the second platen.

47. The method of claim 44, wherein the third chemical mechanical polishing process is performed on a third platen.

48. The method of claim 41, wherein the fourth slurry has an etching selectivity ratio of the patterned hard mask to the conductive layer, and the etching selectivity ratio is greater than 1.

49. The method of claim 29, wherein the patterned hard mask comprises silicon oxide nitride compounds, silicon nitride compounds or siliconcarbon.

50. The method of claim 29, wherein the conductive layer comprises tungsten, aluminum, copper, or an alloy thereof.

51. The method of claim 29, wherein the barrier layer is selected from a group consisting of titanium, tantalum, titanium nitride and tantalum nitride.

52. The method of claim 29, wherein the dielectric layer comprises silicon oxide.
